(19) United States
(12) Patent Application Publication
(10) Pub. No.: US 2012/0164819 A1
(43) Pub. Date: Jun. 28, 2012

(54) APPARATUS AND METHOD FOR MANUFACTURING POLY-SI THIN FILM

(75) Inventors: Jae-Sang RO, Seoul (KR); Won-Eui HONG, Seoul (KR)

(73) Assignee: ENSILTECH CORPORATION, Seoul (KR)

(21) Appl. No.: 12/979,000

(22) Filed: Dec. 27, 2010

(30) Foreign Application Priority Data
Dec. 24, 2010 (KR) 10-2009-0131254

(51) Int. Cl. H01L 21/36; H05B 3/00

(52) U.S. Cl. 438/486; 219/200; 257/E21.461

(57) ABSTRACT

An apparatus and method for fabricating a polycrystalline silicon (poly-Si) thin film are provided. The apparatus includes a chamber, a substrate stage installed at a lower portion in the chamber and on which a substrate including a conductive layer is located, a power application unit installed at an upper portion in the chamber and including an electrode terminal applying power to the conductive layer, and a conductive pad interposed between the electrode terminal and the conductive layer. Thus, it is possible to form a uniform electric field on the conductive layer, and to form a good quality of poly-Si thin film.

### CROSS-REFERENCE TO RELATED APPLICATION

This application claims the benefit of Korean Patent Application No. 2009-0131254, filed Dec. 24, 2009, the disclosure of which is hereby incorporated herein by reference in its entirety.

### BACKGROUND OF THE INVENTION

1. Field of the Invention

The present invention relates to an apparatus and method for fabricating a polycrystalline silicon (poly-Si) thin film, and more particularly, to an apparatus and method for fabricating a poly-Si thin film capable of fabricating the poly-Si thin film by applying power to a substrate to generate Joule heat.

2. Description of the Related Art

In general, amorphous silicon (a-Si) suffers from low mobility of charge carriers, electrons, a low aperture ratio, and incompatibility with a complementary metal oxide semiconductor (CMOS) process, whereas polycrystalline silicon (poly-Si) thin film devices can form a driving circuit required to write a video signal to a pixel along with a pixel thin film transistor (TFT) array on a substrate, which is impossible in a-Si TFTs. Thus, the poly-Si thin film devices do not require connection between a plurality of terminals and a driver integrated circuit (IC), so that the poly-Si thin film devices can increase productivity and reliability, and reduce the thickness of a panel. Further, since micromachining technology of silicon large-scale integration (LSI) can be used in the poly-Si TFT process as it stands, a microstructure can be formed in, for instance, interconnections. Thus, since there is no restriction of pitches when the driver IC of the a-Si TFT is mounted by tape automated bonding (TAB), it is easy to shrink a pixel, and it is possible to realize a plurality of pixel within a small angle of view. In comparison with the TFT using a-Si, the TFT using poly-Si for an active layer is characterized by miniaturization of the device and conversion into CMOS due to high switching capacity and decision of a channel position of the active layer by self-alignment. For this reason, the poly-Si TFT is used as a pixel switch device of, for instance, an active matrix type flat panel display (e.g. a liquid crystal display or an organic electroluminescent (EL) display), and is raised as a main device for conversion into a large screen and commercialization of chip-on-glass (COG) products having a built-in driver.

Meanwhile, the inventors of the present invention has proposed a method of interposing a conductive thin film on or under a silicon thin film, applying an electric field to perform Joule heating, and crystallizing the conductive thin film, which is disclosed in Korean Patent Application No. 2007-0021252.

FIG. 1 is a schematic cross-sectional view showing a conventional method of fabricating a poly-Si thin film, and FIG. 2 is an enlarged view of part “A” of FIG. 1.

First, referring to FIG. 1, the conventional method of fabricating a poly-Si thin film includes forming an amorphous silicon layer 12 on a substrate 11 formed of glass, stainless steel, or plastic, forming an insulating layer 13 such as a silicon oxide layer or a silicon nitride layer on the amorphous silicon layer 12, and forming a conductive layer 14 on the insulating layer 13 using a transparent conductive thin film or a metal thin film.

Then, an electric field is applied to the conductive layer 14 through an electrode terminal 15 installed in an apparatus for fabricating a poly-Si thin film, and thus the amorphous silicon layer 12 is crystallized by Joule heating.

However, in the conventional method of fabricating a poly-Si thin film, as shown in FIG. 2, when a contact surface between the conductive layer and the electrode terminal is not uniform, the surface contact between the conductive layer and the electrode terminal is not uniform, so that a uniform electric field is not formed on the conductive layer, and thus a high quality of poly-Si thin film is not formed.

### SUMMARY OF THE INVENTION

An embodiment of the invention provides an apparatus and method for fabricating a polycrystalline silicon (poly-Si) thin film, capable of forming a uniform electric field on a conductive layer and thus forming a good quality of poly-Si thin film.

In one aspect, there is provided an apparatus for applying an electric field, which includes: a chamber; a substrate stage which is installed at a lower portion in the chamber and on which a substrate including a conductive layer is located; a power application unit installed at an upper portion in the chamber and including an electrode terminal applying power to the conductive layer; and a conductive pad interposed between the electrode terminal and the conductive layer.

In some embodiments, the apparatus may be an apparatus for fabricating a poly-Si thin film.

In another aspect, there is provided a method of fabricating a poly-Si thin film, which includes: providing a substrate having a conductive layer onto a substrate stage installed at a lower portion in a chamber; providing a power application unit located at an upper portion in the chamber and having an electrode terminal; providing a conductive pad between the electrode terminal and the conductive layer; and applying power to the conductive layer from the electrode terminal.

In some embodiments, the conductive pad may include at least one selected from gold, silver, copper, nickel, silver/glass, and silver/copper, and at least one selected from polyurethane and silicon.

### BRIEF DESCRIPTION OF THE DRAWINGS

The foregoing and other objects, features and advantages of the invention will be apparent from the more particular description of an exemplary embodiment of the invention, as illustrated in the accompanying drawing. The drawing is not necessarily to scale, emphasis instead being placed upon illustrating the principles of the invention.

FIG. 1 is a schematic cross-sectional view showing a conventional method of fabricating a polycrystalline silicon (poly-Si) thin film;

FIG. 2 is an enlarged view of part “A” of FIG. 1;

FIG. 3A is a schematic perspective view showing a method of fabricating a poly-Si thin film according to an exemplary embodiment of the present invention;

FIG. 3B is a cross-sectional view taken along line I-I of FIG. 3A;

FIG. 4 is an enlarged view of part “B” of FIG. 3B;

FIG. 5 is a cross-sectional view showing an apparatus for fabricating a poly-Si thin film according to an exemplary embodiment of the present invention;

FIGS. 6A through 6G are cross-sectional views showing examples of an electrode terminal and a conductive pad in accordance with an exemplary embodiment of the present invention;

FIG. 7A is a cross-sectional view showing examples of an electrode terminal and a conductive pad in accordance with an exemplary embodiment of the present invention;

FIG. 7B is an enlarged view of part “C” of FIG. 7A; and

FIG. 7C is a modification of the conductive pad of FIG. 7A.

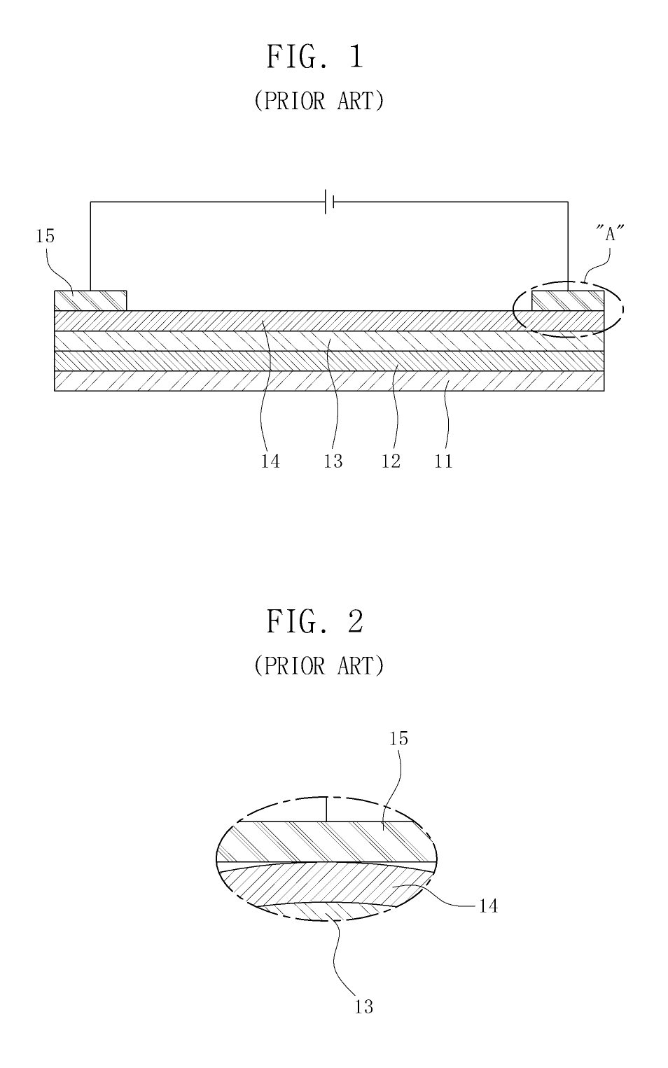

### DETAILED DESCRIPTION OF THE INVENTION

The present invention will now be described more fully hereinafter with reference to the accompanying drawings, in which exemplary embodiments of the invention are shown. This invention may, however, be embodied in different forms and should not be construed as limited to the embodiments set forth herein. Rather, these embodiments are provided so that this disclosure will be thorough and complete, and will fully convey the scope of the invention to those skilled in the art. Like numbers refer to like elements throughout the specification.

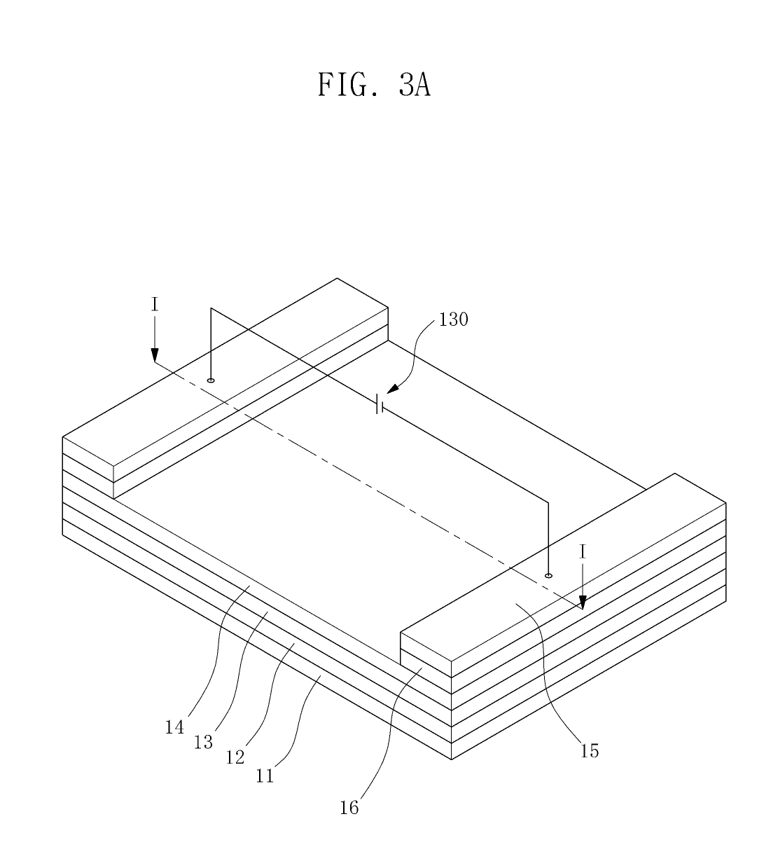

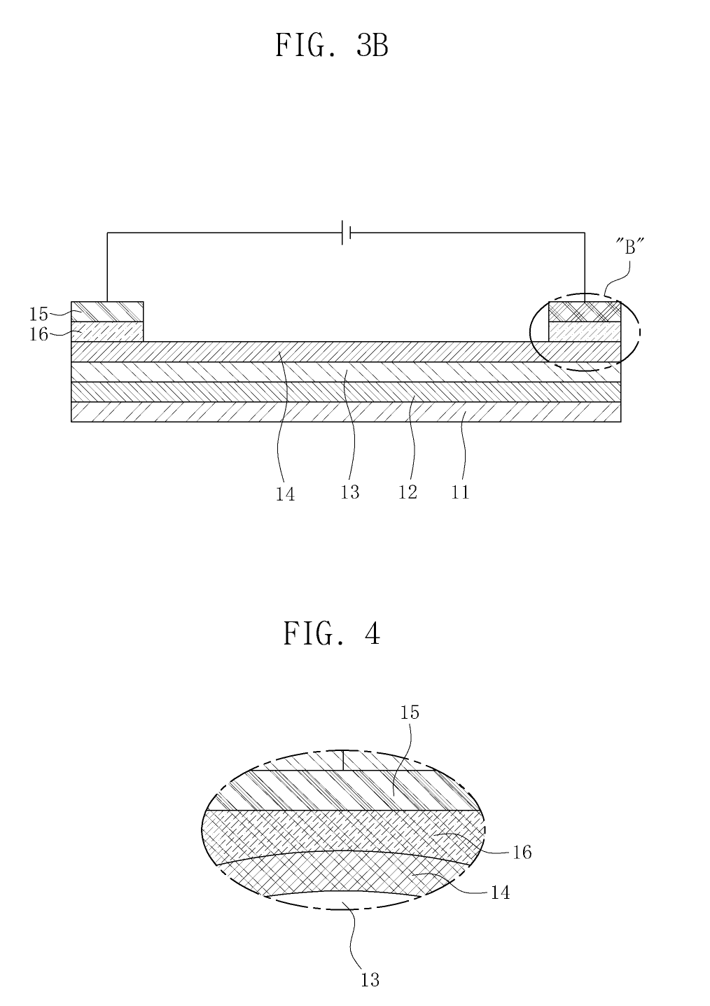

FIG. 3A is a schematic perspective view showing a method of fabricating a polycrystalline silicon (poly-Si) thin film according to an exemplary embodiment of the present invention, and FIG. 3B is a cross-sectional view taken along line I-I of FIG. 3A. FIG. 4 is an enlarged view of part “B” of FIG. 3B.

First, referring to FIGS. 3A and 3B, an amorphous silicon (a-Si) layer 12, an insulating layer 13, and a conductive layer 14 are sequentially formed on a substrate 11. An electric field is applied to the conductive layer 14, thereby inducing Joule heating to generate high-temperature heat. Thereby, the a-Si layer 12 is crystallized by the high-temperature heat.

The substrate 11 is not particularly limited, and may be formed of a material for a transparent substrate, for instance glass, quartz, plastic, or the like, and particularly glass from the economical point of view.

The a-Si layer 12 may be formed by, for instance, low-pressure chemical vapor deposition, atmospheric pressure chemical vapor deposition, plasma enhanced chemical vapor deposition, sputtering, vacuum evaporation, or the like.

The insulating layer 13 serves to prevent the a-Si layer 12 from being contaminated by the conductive layer 14 during heat treatment, and to insulate a thin film transistor (TFT) element, and may be generally formed by depositing silicon oxide (SiO₂) or silicon nitride.

The conductive layer 14 may be formed of a transparent conductive thin film or a metal thin film. The transparent conductive thin film may employ indium tin oxide (ITO) or indium zinc oxide (IZO), and the metal thin film may employ Mo, Ti, Cr, Cu, Au, Ag, Pd, or MoW. However, in the present invention, the conductive layer is not limited to these materials.

The conductive layer 14 may be formed by sputtering or evaporation. The conductive layer 14 may be formed to a thickness from 500 Å to 3000 Å,but it is not limited to this thickness.

In the present invention, as described above, the electric field is applied to the conductive layer, thereby causing Joule heating. Here, the term “Joule heating” refers to heating using heat generated due to resistance when current flows through a conductor.

Thus, an amount of energy per unit time which is applied to the conductive layer by Joule heating caused by the applied electric field can be expressed by the following equation.

W=V×I

where W is the amount of energy per unit time of Joule heating, V is the voltage applied across the conductive layer, and I is the current.

It can be found from this equation that, as the voltage V increases, and/or as the current I becomes higher, the amount of energy per unit time applied to the conductive layer by Joule heating increases. When the temperature of the conductive layer is raised by Joule heating, the a-Si layer 14 is crystallized into a poly-Si layer by high-temperature heat.

Here, the intensity of the electric field is determined by a variety of factors such as resistance, length, and thickness of the conductive layer, and thus is difficult to be specified. The intensity of the electric field may range from about 100 W/cm² to 1,000,000 W/cm². Further, the applied current may be direct current or alternating current. The electric field may be continuously applied for 1/10,000,000 to 10 seconds. Further, the electric field may be regularly or irregularly applied several times.

Here, the electric field is applied to the conductive layer 14 by means of each electrode terminal 15 installed in an apparatus for fabricating a poly-Si thin film. The present invention is characterized in that a conductive pad 16 is interposed between the conductive layer and the electrode terminal.

The conductive pad 16 is made by dispersing one or a mixture of at least two, which are selected from high electrical conductivity metal powders of gold, silver, copper, nickel, silver/glass, and silver/copper, into a liquid polymeric resin such as polyurethane or silicon and mixing the resultant product, and forming the mixture in a planar shape, and has conductivity and a cushion force.

Meanwhile, the conductive pad may be integrally attached to the electrode terminal. To attach the conductive pad to the electrode terminal, a conductive non-substrate or substrate double-sided tape or a conductive adhesive may be used.

In this manner, the conductive pad having conductivity and a cushion force is interposed between the conductive layer and the electrode terminal. As such, in the method of fabricating a poly-Si thin film according to an exemplary embodiment of the present invention, as shown in FIG. 4, although the contact surfaces of the conductive layer and the electrode terminal are not uniform, the conductive pad allows a uniform surface contact, and thus a uniform electric field can be formed to the conductive layer.

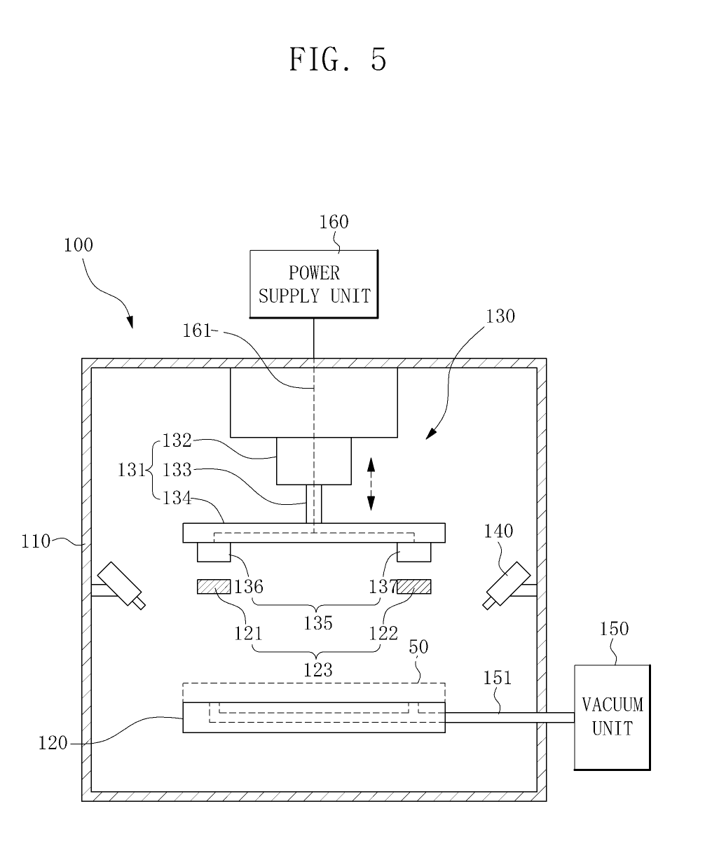

FIG. 5 is a cross-sectional view showing an apparatus for fabricating a poly-Si thin film according to an exemplary embodiment of the present invention.

Referring to FIG. 5, an apparatus 100 for fabricating a poly-Si thin film according to an exemplary embodiment of the present invention includes a chamber 110, a substrate stage 120 installed at a lower portion in the chamber 110, and a power application unit 130 installed at an upper portion in the chamber 110. The substrate stage 120 is installed to face the power application unit 130.

Further, the apparatus 100 for fabricating a poly-Si thin film may further include align check units 140 installed in the chamber 110.

An airtight processing apace is located in the chamber 110 such that the process of fabricating a poly-Si thin film is performed.

The substrate stage 120 serves to accurately align and fix a loaded substrate 50 at a designated position such that the process of fabricating a poly-Si thin film is performed.

Here, the loaded substrate 50 is located on top of the substrate stage 120. The substrate 50 includes the a-Si layer, the insulating layer, and the conductive layer.

Further, the substrate stage 120 may include one or more adsorption holes formed so as to be exposed to the top thereof.

The adsorption holes are connected with a vacuum unit 150 via a vacuum line 151. The vacuum unit 150 provides vacuum, which is for adsorbing and fixing the substrate 50 located on top of the substrate stage 120, to the adsorption holes via the vacuum line 151.

The power application unit 130 applies power to the conductive layer of the substrate 50 aligned and fixed on the substrate stage 120, and may include an electrode movement unit 131 installed at the upper portion in the chamber 110 and an electrode terminal 135 installed on the electrode movement unit 131.

The electrode movement unit 131 includes a cylinder 132 fixed to the upper portion in the chamber 110, a piston 133 coupled to the cylinder 132 reciprocate at a constant distance, and an electrode holder 134 connected with the piston 133. The electrode holder 134 may be a flat plate that is integrally formed with the piston 133.

The electrode terminal 135 is installed on a lower surface, which is a surface facing the substrate stage 120 of the electrode holder 134 to be able to apply power to the conductive layer of the substrate 50.

The electrode terminal 135 is installed such that two electrodes 136 and 137 having different polarities are maintained at a predetermined interval, and is electrically connected to a power supply unit 160 via a power line 161.

The power supply unit 160 supplies power, which is applied to the conductive layer of the substrate 50, to the electrode terminal 135 through the power line 161.

Each align check unit 140 monitors alignment of the substrate 50 with the substrate stage 120 to be able to be checked outside, and may be installed on an inner wall of the chamber 110.

Of course, the align check units 140 may be installed anywhere in the chamber 110 if it can monitor the alignment of the substrate 50 with the substrate stage 120.

Further, the align check units 140 may monitor alignment of the substrate 50 with the electrode terminal 135 when the electrode terminal 135 comes into contact with the substrate 50 in order to apply the power to the substrate 50.

Accordingly, the align check units 140 are installed to monitor respective preset positions, for instance respective corners of the substrate 50, in order to check the alignment.

Furthermore, the align check units 140 may monitor an entire crystallizing process in addition to the alignment of the substrate 50 with the substrate stage 120 and the alignment of the substrate 50 with the electrode terminal 135.

Here, as described above, the present invention is characterized in that conductive pads 123 are installed between the conductive layer of the substrate 50 and the electrode terminal. The conductive pads 123 are divided into two pads 121 and 122 formed on two electrodes 136 and 137 of the electrode terminal, respectively.

The conductive pads may be integrally attached to the electrode terminal, or may be separately provided between the conductive layer and the electrode terminal when the crystallizing process is performed without being attached to the electrode terminal.

However, the present invention is characterized in that the conductive pads are installed between the conductive layer and the electrode terminal, and thus does not restrict construction and geometry of the apparatus for fabricating a poly-Si thin film.

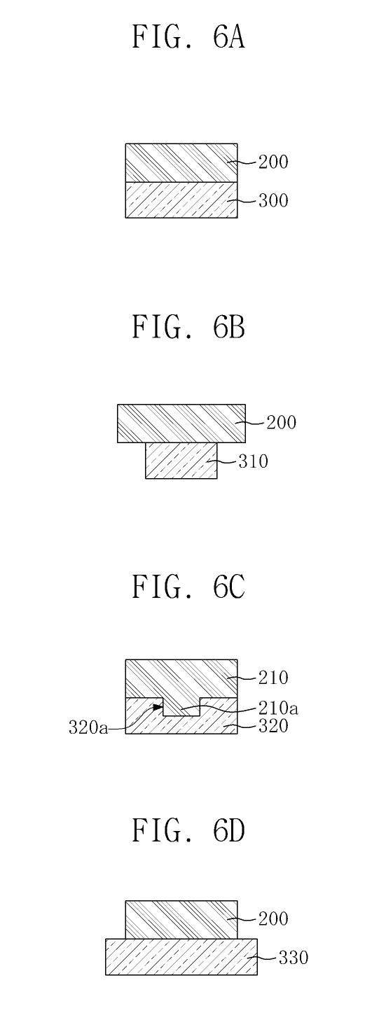

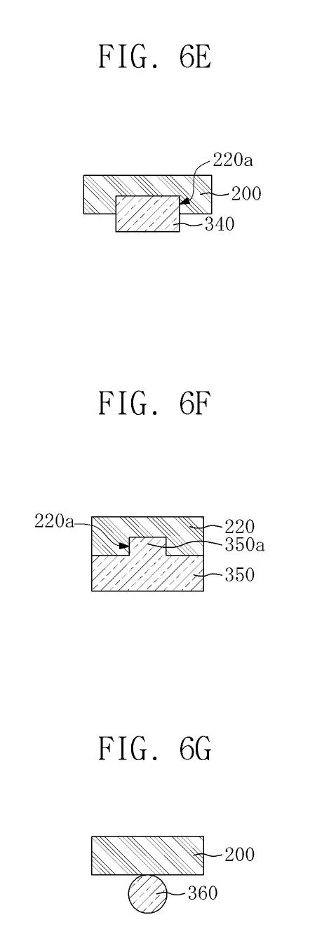

FIGS. 6A through 6G are cross-sectional views showing examples of an electrode terminal and a conductive pad in accordance with an exemplary embodiment of the present invention.

First, as illustrated in FIG. 6A, an electrode terminal 200 may have the same size and shape as a conductive pad 300.

Further, as illustrated in FIG. 6B, the electrode terminal 200 may be formed so as to have a size larger than a conductive pad 310.

Also, as illustrated in FIG. 6C, an electrode terminal 210 may include a protrusion 210a, and a conductive pad 320 may have a recess 320a, so that the protrusion can be fitted into the recess.

Further, as illustrated in FIG. 6D, the electrode terminal 200 may be formed so as to have a size smaller than a conductive pad 330.

Further, as illustrated in FIG. 6E, the electrode terminal 200 may include a recess 220a in such as manner that a conductive pad 340 can be fitted into the recess 220a.

Also, as illustrated in FIG. 6F, the electrode terminal 220 may include a recess 220a, and a conductive pad 350 may have a protrusion 350a, so that the protrusion can be fitted into the recess.

In addition, as illustrated in FIG. 6G, a conductive pad 360 may have a spherical or cylindrical shape.

However, the present invention does not restrict the shapes of the conductive pad and the electrode terminal.

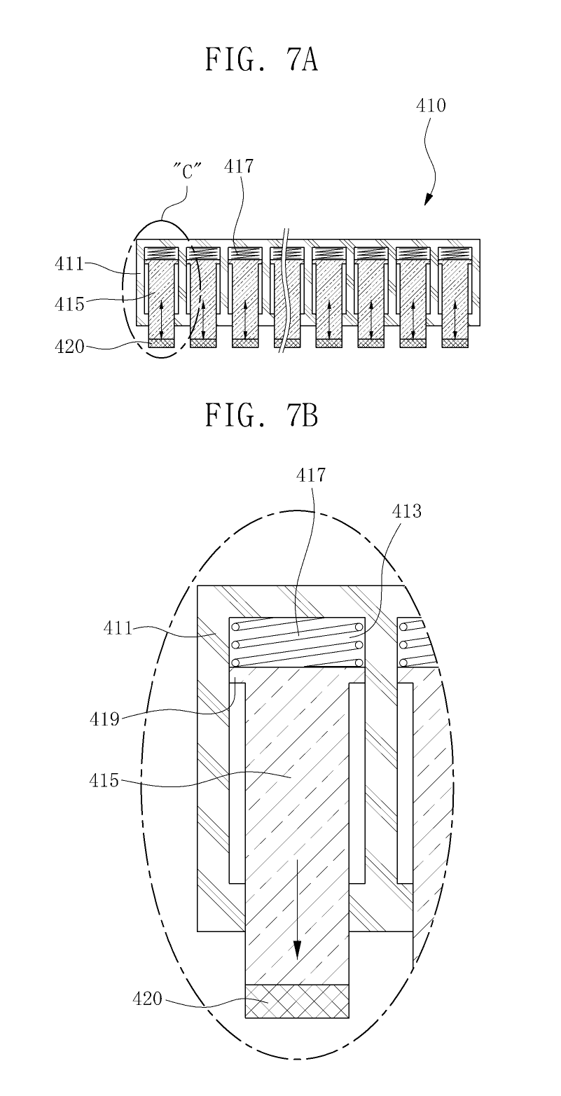

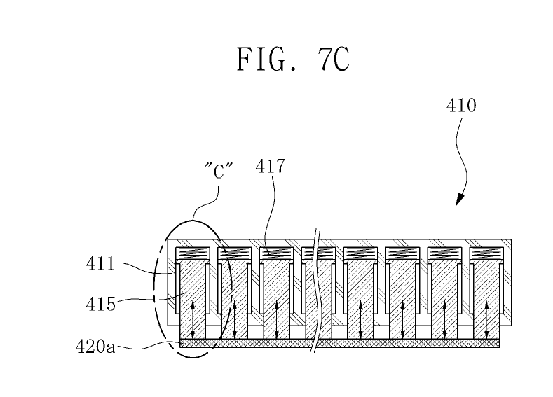

FIG. 7A is a cross-sectional view showing examples of an electrode terminal and a conductive pad in accordance with an exemplary embodiment of the present invention. FIG. 7B is an enlarged view of part “C” of FIG. 7A, and FIG. 7C is a modification of the conductive pad of FIG. 7A.

Referring to FIG. 7A, an electrode terminal 410 is made up of a housing 411, a plurality of rooms 413 formed in the housing 411, and elevation terminal parts 415 elastically installed in the rooms 413 to be able to be elevated.

The housing 411 is provided therein with springs 417, and each elevation terminal part 415 may be provided with a stopper 419 at one end thereof.

Here, during Joule heating, the elevation terminal parts 415 are elastically supported by the spring 417, so that the elevation terminal parts 415 can be in uniform contact with the conductive layer.

The stopper 419 serves to prevent the elevation terminal part 415 elevated in the room 413 of the housing 411 from being arbitrarily separated out of the room 413.

Meanwhile, in the present invention, conductive pads 420 may be attached to the respective elevation terminal parts 415 of the electrode terminal 410. The shapes and sizes of the elevation terminal part 415 and the conductive pad 420 may be constructed as described in FIG. 6.

In detail, although the examples of the electrode terminal and the conductive pad have been shown in FIG. 6, the shape of the elevation terminal part may be constructed as the shape of the electrode terminal of FIG. 6.

On the other hand, as illustrated in FIG. 7C, the conductive pads are not attached to the respective elevation terminal parts, but the conductive pad is enlarged so as to have an enough size to cover the plurality of elevation terminal parts, so that a conductive pad 420a can be provided between the electrode terminal and the conductive layer. Here, the conductive pad may be integrally attached to the elevation terminal parts, or may be separately provided between the conductive layer and the electrode terminal when the crystallizing process is performed without being attached to the electrode terminal.

According to the present invention, an apparatus and method for fabricating a poly-Si thin film can form a uniform electric field on a conductive layer, and thus form a good quality of poly-Si thin film.

Exemplary embodiments of the present invention have been disclosed herein and, although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. An apparatus for applying an electric field, comprising:
a chamber;
a substrate stage installed at a lower portion in the chamber and on which a substrate including a conductive layer is located;
a power application unit installed at an upper portion in the chamber and including an electrode terminal applying power to the conductive layer; and
a conductive pad interposed between the electrode terminal and the conductive layer.

2. The apparatus according to claim 1, wherein the conductive pad includes at least one selected from gold, silver, copper, nickel, silver/glass, and silver/copper, and at least one selected from polyurethane and silicon.

3. The apparatus according to claim 1, wherein the substrate further includes an amorphous silicon (a-Si) layer.

4. The apparatus according to claim 1, wherein the conductive pad is attached to the electrode terminal.

5. The apparatus according to claim 1, wherein the electrode terminal has the same size and shape as the conductive pad.

6. The apparatus according to claim 1, wherein the conductive pad has a size smaller than the electrode terminal.

7. The apparatus according to claim 1, wherein the electrode terminal has a size smaller than the conductive pad.

8. The apparatus according to claim 1, wherein the electrode terminal has a protrusion, and the conductive pad has a recess.

9. The apparatus according to claim 1, wherein the conductive pad has a protrusion, and the electrode terminal has a recess.

10. The apparatus according to claim 1, wherein the electrode terminal has a recess, and the conductive pad is fitted into the recess.

11. The apparatus according to claim 1, wherein the electrode terminal has a housing, a plurality of rooms formed in the housing, and elevation terminal parts elastically installed in the rooms to be able to be elevated.

12. The apparatus according to claim 11, wherein the housing has springs installed therein.

13. The apparatus according to claim 11, wherein each elevation terminal part includes a stopper at one end thereof.

14. The apparatus according to claim 1, wherein the apparatus is an apparatus for fabricating a polycrystalline silicon (poly-Si) thin film.

15. A method of fabricating a polycrystalline silicon (poly-Si) thin film, comprising:
providing a substrate having a conductive layer onto a substrate stage installed at a lower portion in a chamber;
providing a power application unit having an electrode terminal at an upper portion in the chamber;
providing a conductive pad between the electrode terminal and the conductive layer; and
applying power to the conductive layer from the electrode terminal.

16. The method according to claim 15, wherein the conductive pad includes at least one selected from gold, silver, copper, nickel, silver/glass, and silver/copper, and at least one selected from polyurethane and silicon.

17. The method according to claim 15, wherein the substrate further includes an amorphous silicon (a-Si) layer, and the power is applied to the conductive layer to crystallize the a-Si layer into a poly-Si layer.

18. The method according to claim 15, wherein the conductive pad is attached to the electrode terminal.

19. The method according to claim 15, wherein the electrode terminal has the same size and shape as the conductive pad.

20. The method according to claim 15, wherein the conductive pad has a size smaller than the electrode terminal.

21. The method according to claim 15, wherein the electrode terminal has a size smaller than the conductive pad.

22. The method according to claim 15, wherein the electrode terminal has a protrusion, and the conductive pad has a recess.

23. The method according to claim 15, wherein the conductive pad has a protrusion, and the electrode terminal has a recess.

24. The method according to claim 15, wherein the electrode terminal has a recess, and the conductive pad is fitted into the recess.

25. The method according to claim 15, wherein the electrode terminal has a housing, a plurality of rooms formed in the housing, and elevation terminal parts elastically installed in the rooms to be able to be elevated.

26. The method according to claim 25, wherein the housing has springs installed therein.

27. The method according to claim 25, wherein each elevation terminal part includes a stopper at one end thereof.
